(19) United States
(12) Patent Application Publication
(10) Pub. No.: US 2023/0389187 A1
(43) Pub. Date: Nov. 30, 2023

(54) CONDUCTIVE MODULE

(71) Applicant: YAZAKI CORPORATION, Tokyo (JP)

(72) Inventor: Hidehiko Shimizu, Makinohara-shi (JP)

(21) Appl. No.: 18/320,953

(22) Filed: May 19, 2023

(30) Foreign Application Priority Data
May 26, 2022 (JP) 2022-085746

(51) Int. Cl. H05K 1/18; H01M 50/519; H01M 50/505

(52) U.S. Cl. CPC H05K 1/189; H01M 50/519; H01M 50/505; H05K 2201/10022; H05K 2201/10151; H05K 2201/10181; H05K 2201/10272; H05K 2201/2018; H05K 2201/10636; H05K 2201/2009

(57) ABSTRACT

A conductive module includes: a flexible printed wiring board; an electronic component that is mounted on the flexible printed wiring board and connected to a circuit pattern of the flexible printed wiring board; a metal plate that includes a frame part surrounding the electronic component and being fixed to the flexible printed wiring board; and a potting agent that is filled in a region surrounded by the frame part to cover the electronic component.

### CROSS-REFERENCE TO RELATED APPLICATION(S)

The present application claims priority to and incorporates by reference the entire contents of Japanese Patent Application No. 2022-085746 filed in Japan on May 26, 2022.

### BACKGROUND OF THE INVENTION

### 1. Field of the Invention

The present invention relates to a conductive module.

### 2. Description of the Related Art

In the related art, there is known a conductive module including a flexible printed wiring board. Japanese Patent Application Laid-open No. 2002-093995 discloses a technique of configuring a power circuit board in which each busbar made of a metallic body is arranged on a surface of a metal board via a flexible board, an IGBT is connected to each busbar, and a three-phase inverter circuit is mounted.

In a case in which an electronic component is mounted on the flexible printed wiring board, it is desirable to appropriately protect the electronic component.

### SUMMARY OF THE INVENTION

The present invention aims at providing a conductive module that can appropriately protect the electronic component mounted on the flexible printed wiring board.

In order to achieve the above mentioned object, a conductive module according to one aspect of the present invention includes a flexible printed wiring board; an electronic component that is mounted on the flexible printed wiring board and connected to a circuit pattern of the flexible printed wiring board; a metal plate that includes a frame part surrounding the electronic component and being fixed to the flexible printed wiring board; and a potting agent that is filled in a region surrounded by the frame part to cover the electronic component.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a plan view of a conductive module according to an embodiment;

FIG. 2 is a cross-sectional view of the conductive module according to the embodiment;

FIG. 3 is a plan view of the conductive module according to the embodiment;

FIG. 4 is a cross-sectional view of the conductive module according to the embodiment;

FIG. 5 is a plan view of the conductive module according to the embodiment;

FIG. 6 is a plan view of the conductive module according to the embodiment;

FIG. 7 is a cross-sectional view of the conductive module according to the embodiment;

FIG. 8 is a plan view of the conductive module according to the embodiment;

FIG. 9 is a plan view of the conductive module according to the embodiment;

FIG. 10 is a plan view of the conductive module according to the embodiment;

FIG. 11 is a plan view of the conductive module according to the embodiment;

FIG. 12 is a cross-sectional view of the conductive module according to the embodiment;

FIG. 13 is a plan view of the conductive module according to the embodiment;

FIG. 14 is a plan view of a conductive module according to a first modification of the embodiment;

FIG. 15 is a plan view of the conductive module according to the first modification of the embodiment;

FIG. 16 is a plan view of a conductive module according to a second modification of the embodiment;

FIG. 17 is a cross-sectional view of the conductive module according to the second modification of the embodiment;

FIG. 18 is a cross-sectional view of the conductive module according to the second modification of the embodiment;

FIG. 19 is a plan view of the conductive module according to the second modification of the embodiment;

FIG. 20 is a cross-sectional view of the conductive module according to the second modification of the embodiment; and

FIG. 21 is a cross-sectional view of the conductive module according to the second modification of the embodiment.

### DETAILED DESCRIPTION OF THE PREFERRED EMBODIMENTS

The following describes a conductive module according to an embodiment of the present invention in detail with reference to the drawings. The present invention is not limited to the embodiment. Constituent elements in the following embodiment encompass a constituent element that is easily conceivable by those skilled in the art, or substantially the same constituent element.

### EMBODIMENT

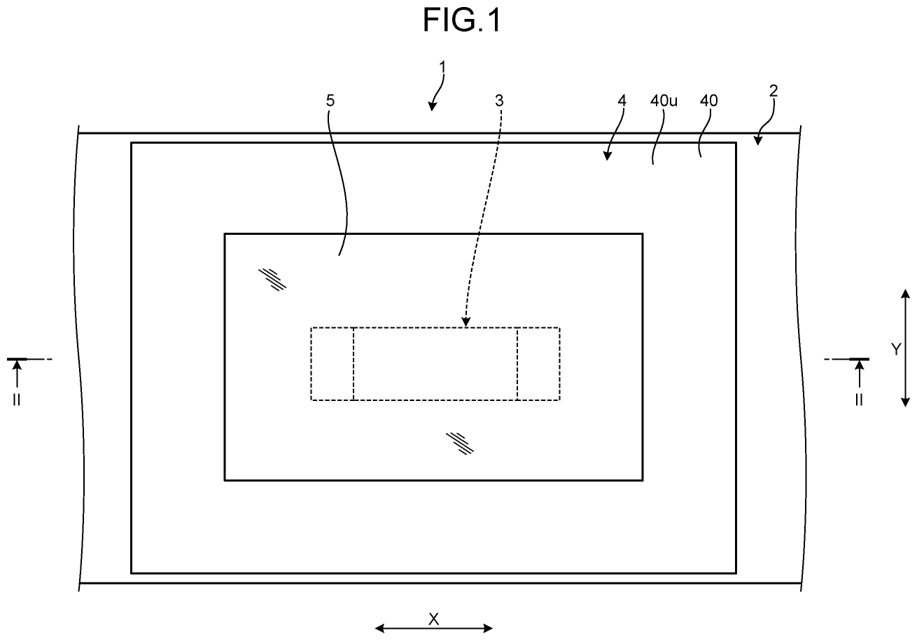

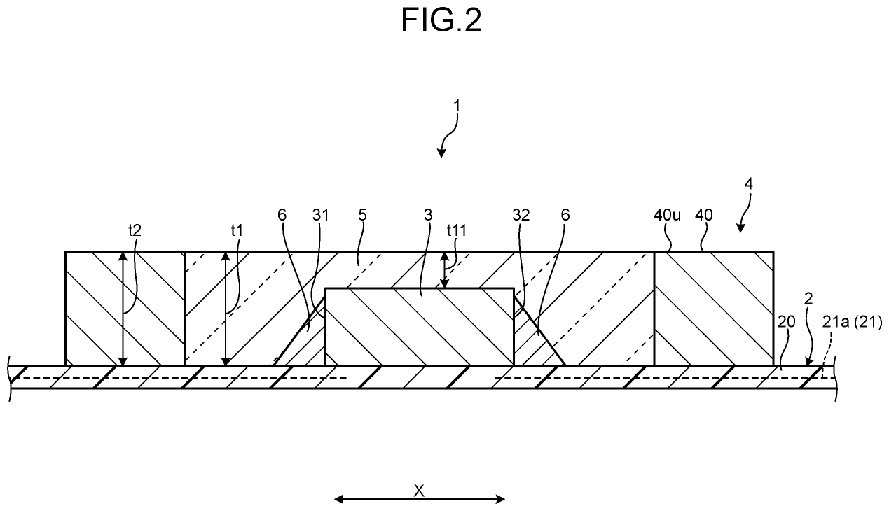

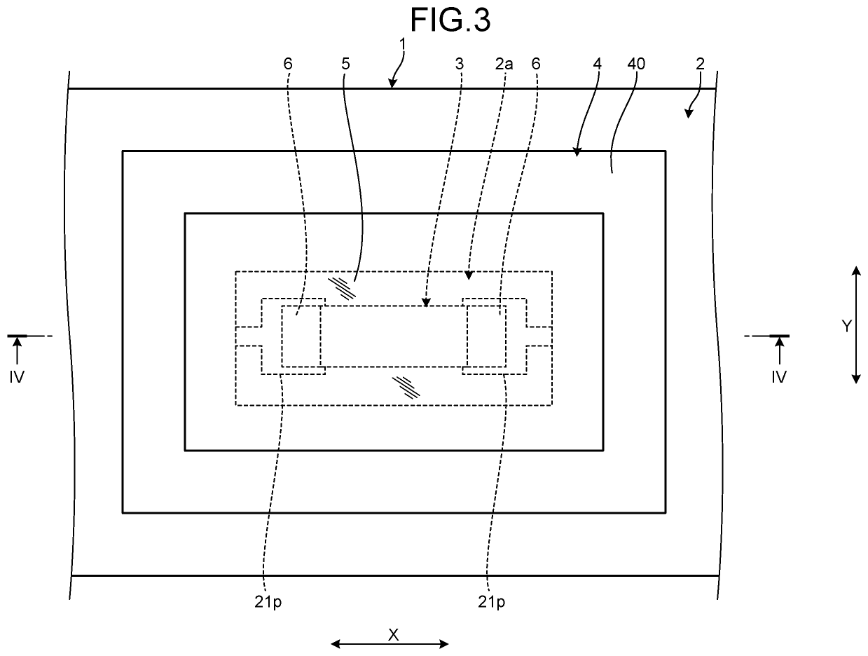

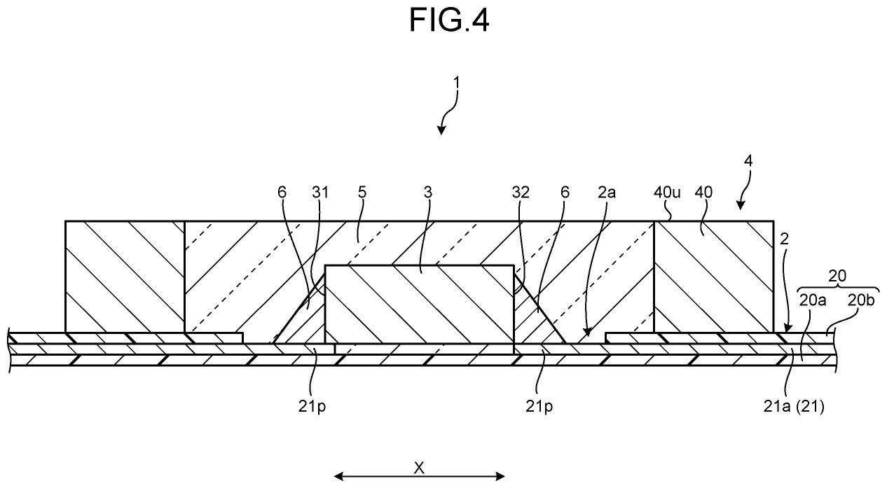

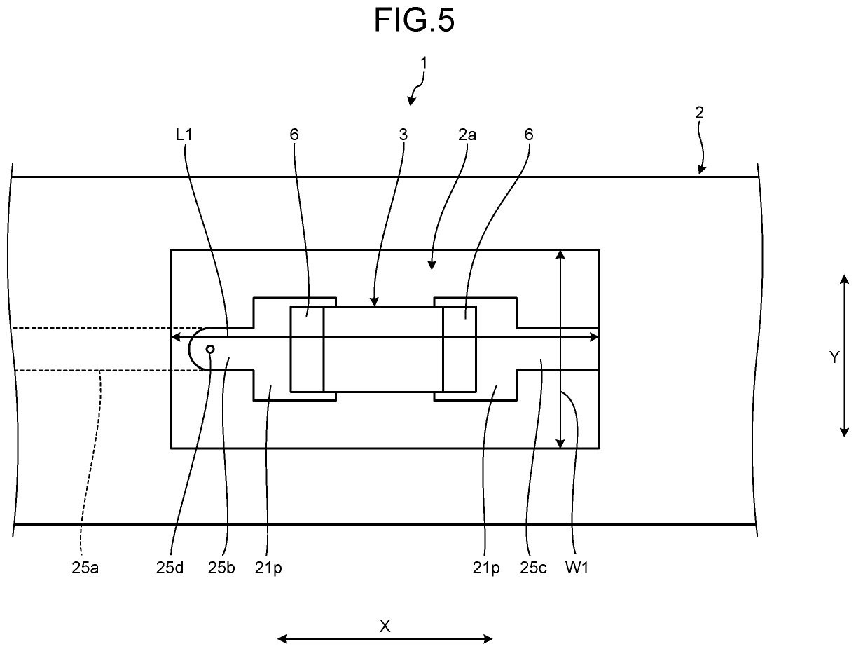

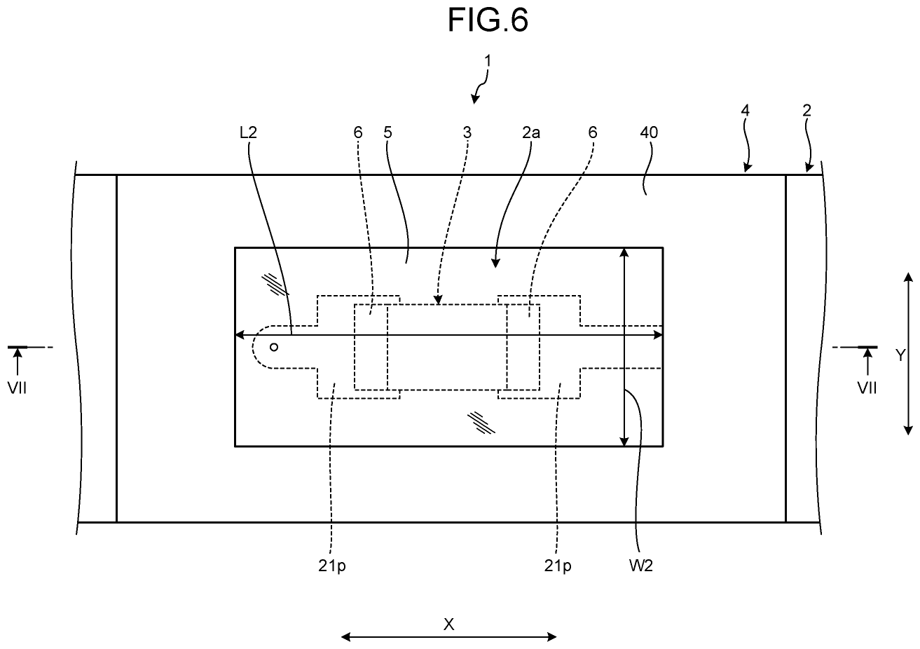

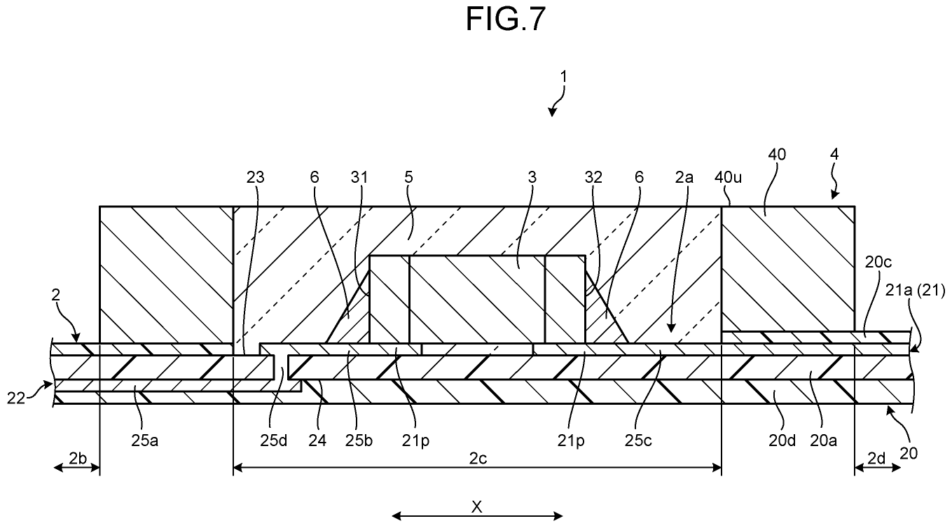

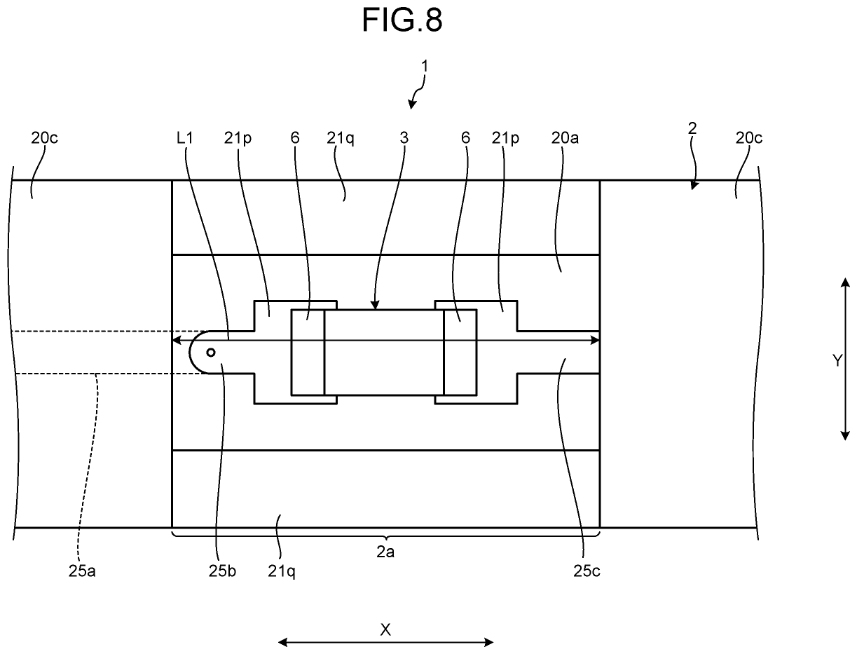

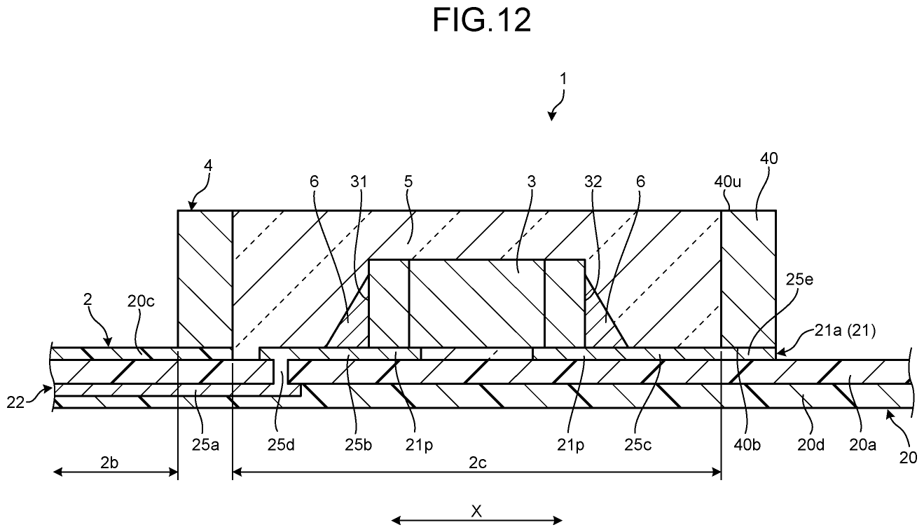

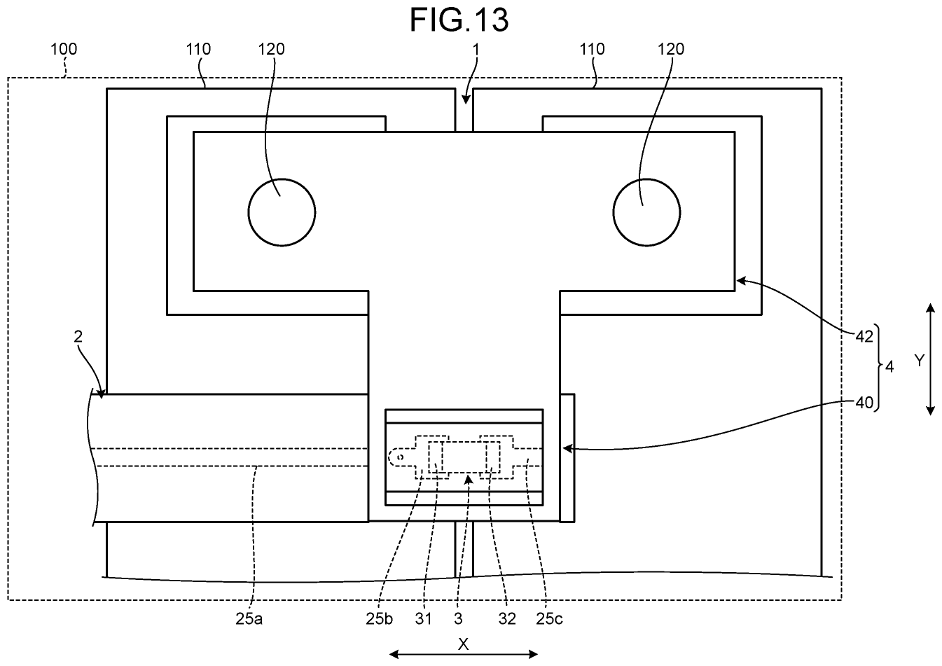

With reference to FIG. 1 to FIG. 13, the following describes the embodiment. The present embodiment relates to a conductive module. FIG. 1, FIG. 3, FIG. 5, FIG. 6, FIG. 8 to 11, and FIG. 13 are plan views of the conductive module according to the embodiment, and FIG. 2, FIG. 4, FIG. 7, and FIG. 12 are cross-sectional views of the conductive module according to the embodiment.

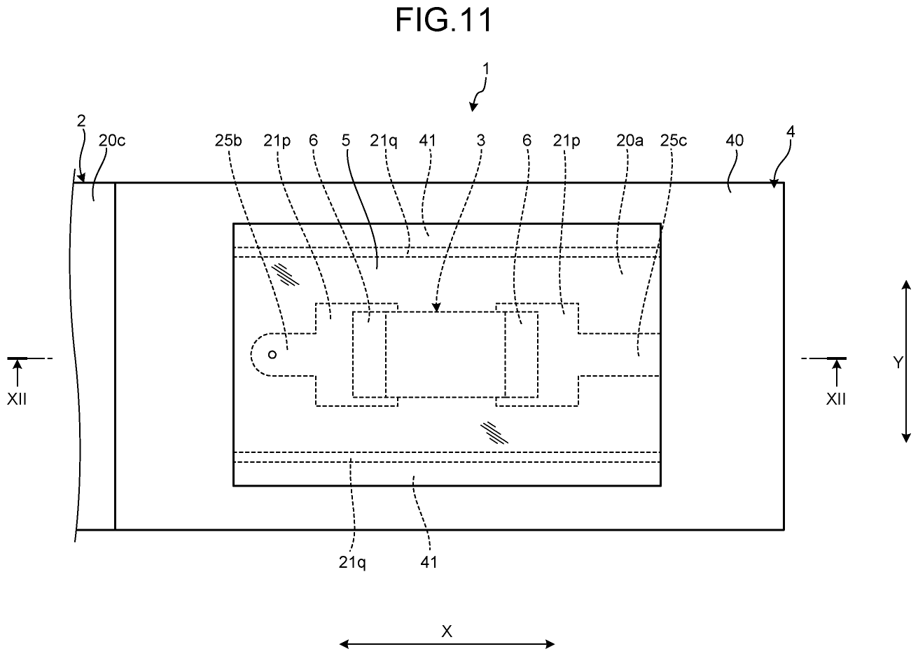

FIG. 2 illustrates a II-II cross section of FIG. 1. FIG. 4 illustrates a IV-IV cross section of FIG. 3. FIG. 7 illustrates a VII-VII cross section of FIG. 6. FIG. 12 illustrates a XII-XII cross section of FIG. 11.

As illustrated in FIG. 1 and FIG. 2, a conductive module 1 according to the present embodiment includes a flexible printed wiring board 2, an electronic component 3, a metal plate 4, and a potting agent 5. The flexible printed wiring board 2 is a printed board having flexibility. In the following description, a longitudinal direction of the flexible printed wiring board 2 is referred to as a “first direction X”, and a width direction thereof is referred to as a “second direction Y”.

As illustrated in FIG. 2, the flexible printed wiring board 2 includes a resin layer 20 and a first conductive layer 21. The resin layer 20 is formed of a synthetic resin having an insulation property. The first conductive layer 21 is a metal layer having electrical conductivity arranged inside the resin layer 20, for example, metal foil. The first conductive layer 21 constitutes a circuit pattern 21a. The resin layer 20 includes, for example, a base film and a coverlay that sandwich the first conductive layer 21.

The electronic component 3 is mounted on the flexible printed wiring board 2, and connected to the circuit pattern 21a. The electronic component 3 is a component including a first terminal part 31 and a second terminal part 32, and may be a chip component. The first terminal part 31 and the second terminal part 32 are connected to the corresponding circuit pattern 21a by solder 6.

The metal plate 4 is a plate-shaped member formed of metal. The metal plate 4 includes a frame part 40 having a flat plate shape and surrounding the electronic component 3. The exemplified frame part 40 has a rectangular frame shape. The frame part 40 is fixed to the flexible printed wiring board 2. The frame part 40 is, for example, bonded to the resin layer 20.

The metal plate 4 reinforces the flexible printed wiring board 2, and protects the electronic component 3 against external stress. The metal plate 4, for example, can regulate bending or stretching of the flexible printed wiring board 2. The metal plate 4 surrounds the electronic component 3, and can suppress interference between the electronic component 3 and other surrounding components.

The potting agent 5 is filled in a region surrounded by the frame part 40 to cover the electronic component 3. The potting agent 5 is, for example, resin having an insulation property. The potting agent 5 can improve moisture resistance and insulation resistance of the electronic component 3.

The potting agent 5 is, for example, filled up to an upper surface 40u of the frame part 40. In other words, a thickness t1 of the filled potting agent 5 is equivalent to a thickness t2 of the frame part 40. The thickness t2 of the frame part 40 is determined so that a thickness t1l of the potting agent 5 covering the electronic component 3 becomes an appropriate thickness.

The coverlay may be removed in a region in which the electronic component 3 is mounted. FIG. 3 and FIG. 4 illustrate the electronic component 3 mounted in an exposed region 2a. As illustrated in FIG. 4, the resin layer 20 includes a base film 20a and a coverlay 20b. The first conductive layer 21 is sandwiched between the base film 20a and the coverlay 20b. The coverlay 20b is removed in a region in which the electronic component 3 is mounted. In other words, in the flexible printed wiring board 2, the exposed region 2a in which the circuit pattern 21a and the base film 20a are exposed is disposed at a portion on which the electronic component 3 is mounted.

As illustrated in FIG. 3, the first conductive layer 21 includes two pads 21p arranged in the exposed region 2a. The electronic component 3 is connected to the pads 21p by the solder 6. The exemplified frame part 40 is arranged on an outer side of the exposed region 2a to surround the exposed region 2a. The potting agent 5 is filled in a region surrounded by the frame part 40 to cover the electronic component 3. As illustrated in FIG. 4, the potting agent 5 is also filled in a space part generated between the two pads 21p. Due to this, an insulation property between the two pads 21p is improved.

In the conductive module 1 illustrated in FIG. 5 to FIG. 7, the exposed region 2a has a size equivalent to an opening of the frame part 40 or a size equal to or larger than the opening. The shape of the exposed region 2a illustrated in FIG. 5 is a rectangle. A length L1 of the exposed region 2a illustrated in FIG. 5 is equal to or larger than an opening length L2 (refer to FIG. 6) of the frame part 40. A width W1 of the exposed region 2a is equal to or larger than an opening width W2 (refer to FIG. 6) of the frame part 40. The two pads 21p are arranged in the exposed region 2a.

FIG. 6 illustrates a state in which the frame part 40 is fixed to the flexible printed wiring board 2, and the potting agent 5 is filled therein. The frame part 40 covers an edge surrounding the exposed region 2a. The potting agent 5 is filled in the opening of the frame part 40 to cover the electronic component 3.

As illustrated in FIG. 7, the flexible printed wiring board 2 includes the base film 20a, the first conductive layer 21, a second conductive layer 22, a first coverlay 20c, and a second coverlay 20d. The first conductive layer 21 is arranged on a first surface 23 of the base film 20a, and the second conductive layer 22 is arranged on a second surface 24 of the base film 20a. The first surface 23 is a surface opposed to the frame part 40. The second surface 24 is a surface of the base film 20a on the opposite side of the first surface 23. The first coverlay 20c covers the first conductive layer 21 and the first surface 23. The second coverlay 20d covers the second conductive layer 22 and the second surface 24.

The circuit pattern 21a of the flexible printed wiring board 2 includes a first wiring part 25a, a second wiring part 25b, and a third wiring part 25c. The first wiring part 25a is constituted of the second conductive layer 22, and extends in the first direction X. The first wiring part 25a extends from a region 2b on the outside of the frame part 40 to an inside region 2c surrounded by the frame part 40.

The second wiring part 25b is constituted of the first conductive layer 21, and arranged in the inside region 2c. The second wiring part 25b is connected to the first wiring part 25a via a via hole 25d. The second wiring part 25b includes the pad 21p corresponding to the first terminal part 31 of the electronic component 3. The first terminal part 31 is connected to the corresponding pad 21p by the solder 6. That is, the second wiring part 25b connects the first wiring part 25a to the first terminal part 31.

The third wiring part 25c is constituted of the first conductive layer 21, and extends from the inside region 2c to an outside region 2d along the first direction X. The third wiring part 25c includes the pad 21p corresponding to the second terminal part 32 of the electronic component 3. The second terminal part 32 is connected to the corresponding pad 21p by the solder 6. The potting agent 5 is filled in a through hole of the frame part 40, and covers an exposed part of the first conductive layer 21 and the electronic component 3. Thus, an insulation property between the metal plate 4 and the electronic component 3 is secured.

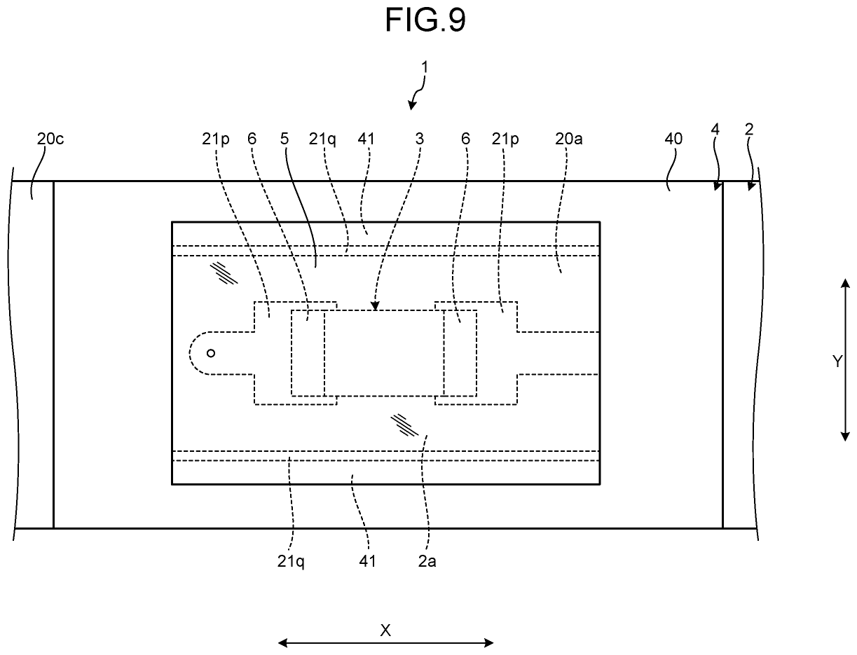

FIG. 8 and FIG. 9 illustrate the conductive module 1 in which the metal plate 4 is fixed by solder. As illustrated in FIG. 8, in the exposed region 2a, the first coverlay 20c is removed from one end to the other end in the second direction Y. Two pads 21q are disposed in the exposed region 2a. The two pads 21q are arranged at both end parts in the second direction Y. The pad 21q is part of the first conductive layer 21, and independent of the circuit pattern.

The flexible printed wiring board 2 includes the first wiring part 25a, the second wiring part 25b, and the third wiring part 25c. Configurations of the wiring parts 25a, 25b, and 25c are the same as the configurations illustrated in FIG. 7, etc. The pad 21q is separated from the second wiring part 25b and the third wiring part 25c.

FIG. 9 illustrates a state in which the frame part 40 is fixed to the flexible printed wiring board 2, and the potting agent 5 is filled therein. The frame part 40 is connected to the pad 21q by solder 41. The potting agent 5 is filled in the opening of the frame part 40 to cover the electronic component 3. An insulation property between the metal plate 4 and the electronic component 3 is secured by the potting agent 5.

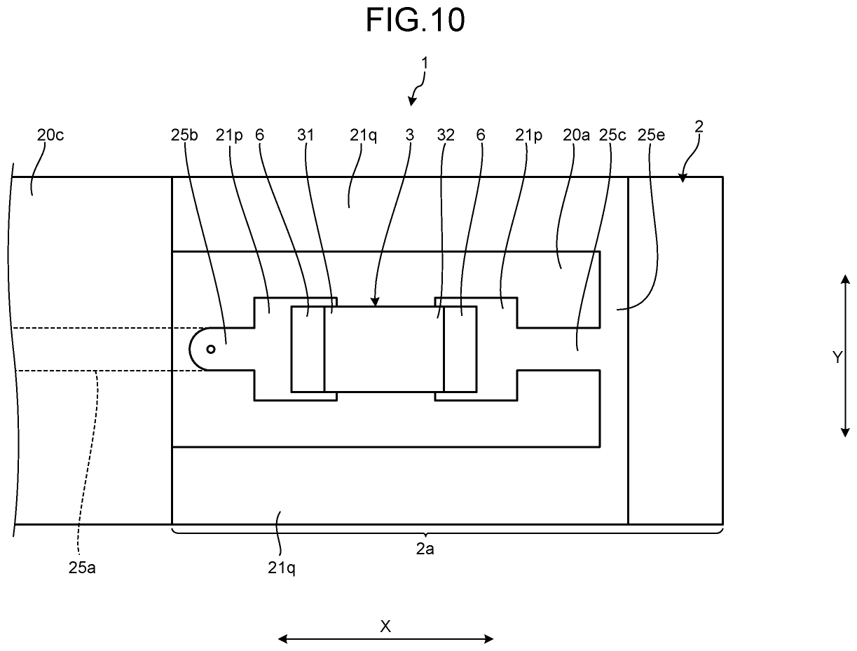

FIG. 10 to FIG. 12 illustrate the conductive module 1 in which the metal plate 4 is connected to the third wiring part 25c. As illustrated in FIG. 10, the exposed region 2a is arranged at a distal end part of the flexible printed wiring board 2. In the exposed region 2a, the first coverlay 20c is removed from one end to the other end in the second direction Y. Two pads 21q are disposed in the exposed region 2a. The two pads 21q are connected to the third wiring part 25c. The exemplified pads 21q are integrated with the third wiring part 25c. The third wiring part 25c includes an opposed part 25e opposed to the frame part 40. The opposed part 25e extends along the second direction Y, and is connected to the pad 21q.

FIG. 11 and FIG. 12 illustrate a state in which the frame part 40 is fixed to the flexible printed wiring board 2, and the potting agent 5 is filled therein. The frame part 40 is connected to the pad 21q by the solder 41. The potting agent 5 is filled in the through hole of the frame part 40, and covers the electronic component 3. The frame part 40 is connected to the third wiring part 25c of the circuit pattern 21a. The frame part 40 is connected to the third wiring part 25c via at least the solder 41 and the pad 21q. As illustrated in FIG. 12, the opposed part 25e of the third wiring part 25c is opposed to a bottom surface 40b of the frame part 40. The opposed part 25e may be in contact with the bottom surface 40b. The third wiring part 25c connects the second terminal part 32 of the electronic component 3 to the frame part 40.

The conductive module 1 illustrated in FIG. 13 is configured as a busbar module. The conductive module 1 is arranged in a battery module 100. The battery module 100 includes a plurality of battery cells 110. The conductive module 1 is placed on the battery cells 110 such that the first direction X of which is aligned with an arrangement direction of the battery cells 110.

The metal plate 4 illustrated in FIG. 13 is a busbar formed of metal having electrical conductivity. The metal plate 4 includes the frame part 40 and a connection part 42. The frame part 40 and the connection part 42, for example, may be integrally formed of the same base metal, or may be formed by joining different members. The shape of the connection part 42 is, for example, a flat plate shape. The connection part 42 projects from the frame part 40 toward the outside of the flexible printed wiring board 2 along the second direction Y. That is, the connection part 42 projects from the frame part 40 toward a lateral side of the flexible printed wiring board 2.

The connection part 42 is connected to two electrodes 120. One of the electrodes 120 is an electrode included in one of the battery cells 110, and the other one of the electrodes 120 is an electrode included in the other one of the battery cells 110. The two electrodes 120 may be a combination of an anode and a cathode.

The frame part 40 illustrated in FIG. 13 is connected to the third wiring part 25c similarly to the frame part 40 illustrated in FIG. 12. That is, the metal plate 4 in FIG. 13 connects the second terminal part 32 of the electronic component 3 to the electrode 120. In this case, the first terminal part 31 of the electronic component 3 may be connected to a control unit that monitors a state of the battery module 100. The electronic component 3 is, for example, a chip fuse.

In the conductive module 1 illustrated in FIG. 13, the metal plate 4 has a plurality of functions. One of the functions is a function as a busbar. The other one of the functions is a function as a reinforcing component of the flexible printed wiring board 2. The further other one of the functions is a function of housing the potting agent 5. Thus, the number of components can be reduced as compared with a case in which a reinforcing plate different from the metal plate 4 is used for the conductive module 1. The conductive module 1 may also include a case that houses the flexible printed wiring board 2 and the metal plate 4.

The electronic component 3 mounted on the flexible printed wiring board 2 is not limited to the fuse. The electronic component 3 may also be a thermistor that detects a temperature of the battery cell 110. In this case, the frame part 40 may be not necessarily connected to the electronic component 3, and the metal plate 4 may be not limited to the busbar. The electronic component 3 may be a chip resistor, or may be another electronic component.

A plurality of the electronic components 3 may be mounted on the flexible printed wiring board 2. In this case, the different metal plates 4 may be arranged for the respective electronic components 3. The plural electronic components 3 may include different components. For example, part of the plural electronic components 3 may be chip fuses, and the other part of the electronic components 3 may be thermistors.

The one frame part 40 may surround a plurality of the electronic components 3. For example, the one frame part 40 may surround the chip fuse and the thermistor. In this case, the potting agent 5 filled in the frame part 40 preferably covers both of the chip fuse and the thermistor.

As described above, the conductive module 1 according to the present embodiment includes the flexible printed wiring board 2, the electronic component 3, the metal plate 4, and the potting agent 5. The electronic component 3 is mounted on the flexible printed wiring board 2, and connected to the circuit pattern 21a of the flexible printed wiring board 2. The metal plate 4 includes the frame part 40 surrounding the electronic component 3, and the frame part 40 is fixed to the flexible printed wiring board 2. The potting agent 5 is filled in the region surrounded by the frame part 40 to cover the electronic component 3. In the conductive module 1 according to the present embodiment, the frame part 40 reinforces the flexible printed wiring board 2 to protect the electronic component 3 against external stress. The potting agent 5 covers the electronic component 3 to protect the electronic component 3. Thus, the electronic component 3 is appropriately protected.

The metal plate 4 disclosed in FIG. 13 according to the present embodiment is a conductive busbar including the connection part 42 fixed to the battery cell 110. The connection part 42 projects from the frame part 40 toward the lateral side of the flexible printed wiring board 2. The frame part 40 is connected to the circuit pattern 21a. In this configuration, the electronic component 3 can be protected by the frame part 40 as part of the busbar.

The flexible printed wiring board 2 according to the present embodiment disclosed in FIG. 10 to FIG. 13, etc., includes the base film 20a, the first conductive layer 21, the first coverlay 20c, the second conductive layer 22, and the second coverlay 20d. The first conductive layer 21 is formed on the first surface 23 of the base film 20a, and covered by the first coverlay 20c. The second conductive layer 22 is formed on the second surface 24 of the base film 20a, and covered by the second coverlay 20d. The first surface 23 is a surface opposed to the frame part 40, and the second surface 24 is a surface on the opposite side of the first surface 23.

The circuit pattern 21a includes the first wiring part 25a, the second wiring part 25b, and the third wiring part 25c. The first wiring part 25a is constituted of the second conductive layer 22, and extends from the region 2b on the outside of the frame part 40 to the inside region 2c surrounded by the frame part 40. The second wiring part 25b is constituted of the first conductive layer 21, arranged in the inside region 2c, and connects the first wiring part 25a to the first terminal part 31 of the electronic component 3. The third wiring part 25c is constituted of the first conductive layer 21, and connects the second terminal part 32 of the electronic component 3 to the frame part 40. By causing the circuit pattern 21a to bypass toward the second surface 24, the frame part 40 can be arranged to be closer to the exposed region 2a.

### First Modification of Embodiment

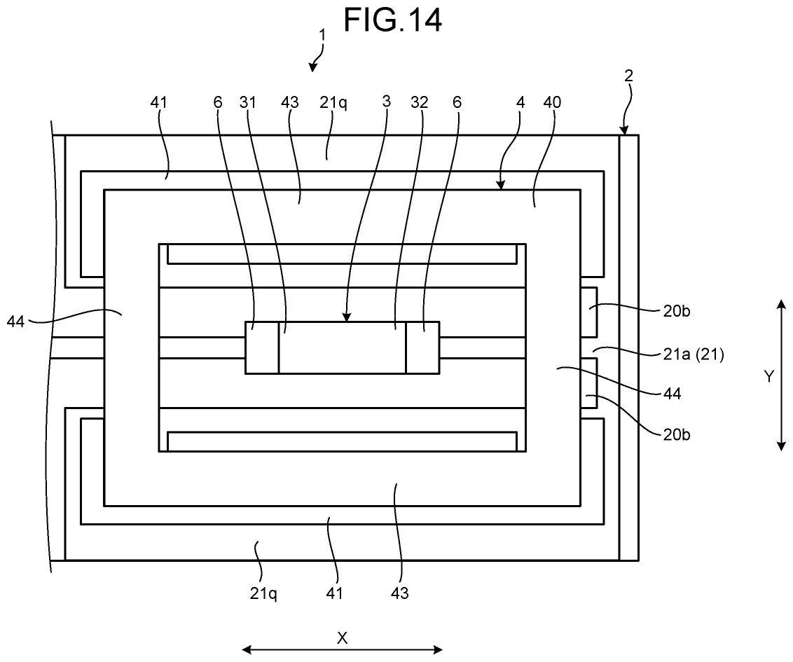

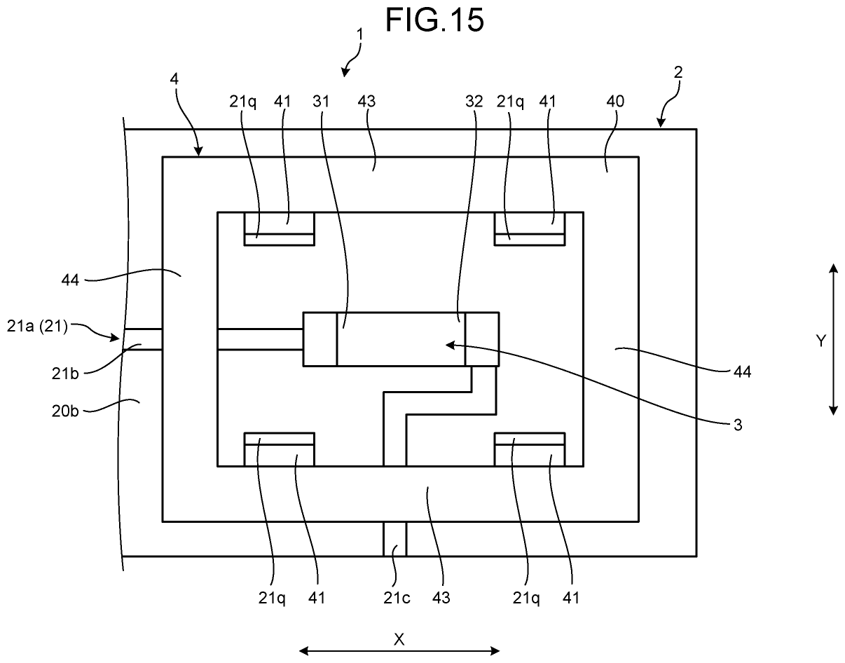

The following describes a first modification of the embodiment. FIG. 14 and FIG. 15 are plan views of the conductive module according to the first modification of the embodiment. The first modification of the embodiment is different from the embodiment described above in that, for example, the circuit pattern 21a three-dimensionally intersects the frame part 40.

The frame part 40 illustrated in FIG. 14 includes a pair of first extending parts 43 and a pair of second extending parts 44. The first extending part 43 extends in a linear shape along the first direction X. The second extending part 44 extends in a linear shape along the second direction Y. An end part of the second extending part 44 is connected to an end part of the first extending part 43. As described below, the second extending part 44 is separated from the circuit pattern 21a, and intersects the circuit pattern 21a.

The first conductive layer 21 includes the circuit pattern 21a and a pair of the pads 21q. The two pads 21q are arranged on both sides in the second direction Y of the circuit pattern 21a to be separated from the circuit pattern 21a. The coverlay 20b is left between the circuit pattern 21a and the pad 21q.

The frame part 40 is placed on the flexible printed wiring board 2 while causing one of the first extending parts 43 to be opposed to one of the pads 21q and causing the other one of the first extending parts 43 to be opposed to the other one of the pads 21q. The first extending part 43 is connected to the pad 21q by the solder 41. The second extending part 44 is placed on the coverlay 20b, and three-dimensionally intersects the circuit pattern 21a. That is, the circuit pattern 21a is routed through an opening formed between the second extending part 44 and the flexible printed wiring board 2.

The potting agent 5 is filled in the region surrounded by the frame part 40. The potting agent 5 can enter a gap between the second extending part 44 and the flexible printed wiring board 2 to insulate the circuit pattern 21a from the second extending part 44.

The flexible printed wiring board 2 illustrated in FIG. 15 includes a plurality of the pads 21q for the one first extending part 43. The exemplified first conductive layer 21 includes the two pads 21q for the one first extending part 43. The two pads 21q are arranged to be separated from each other in the first direction X. The one first extending part 43 is connected to each of the two pads 21q by the solder 41. Between the two pads 21q, a gap is formed between the first extending part 43 and the first conductive layer 21.

The exemplified circuit pattern 21a includes a first circuit 21b connected to the first terminal part 31 and a second circuit 21c connected to the second terminal part 32. The first circuit 21b passes through an opening between the second extending part 44 and the flexible printed wiring board 2. The second circuit 21c passes through an opening between the first extending part 43 and the flexible printed wiring board 2.

The conductive module 1 according to the first modification of the embodiment can improve a degree of freedom of the circuit pattern 21a while protecting the electronic component 3 by the metal plate 4.

### Second Modification of Embodiment

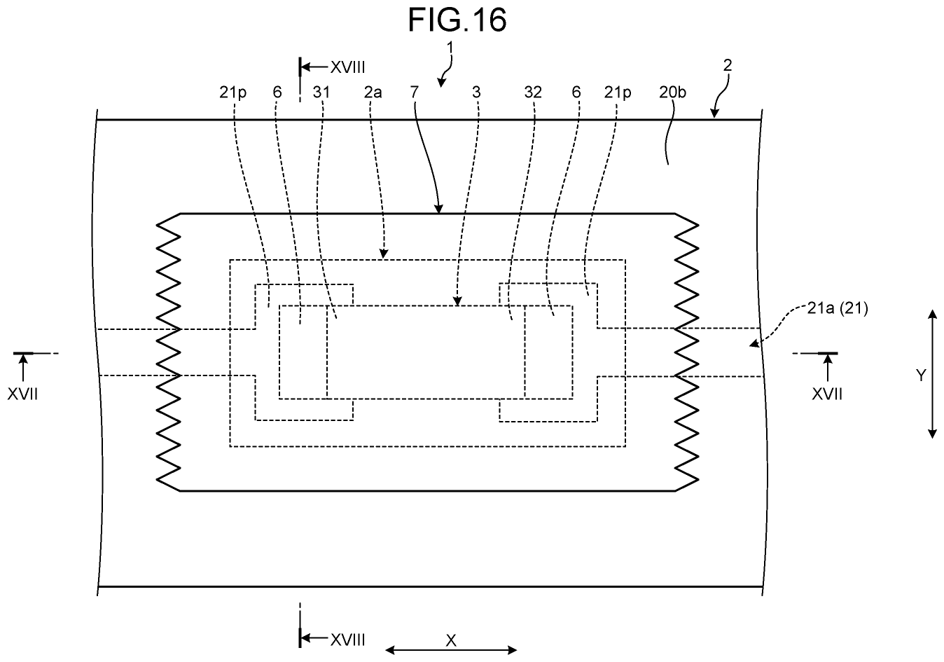

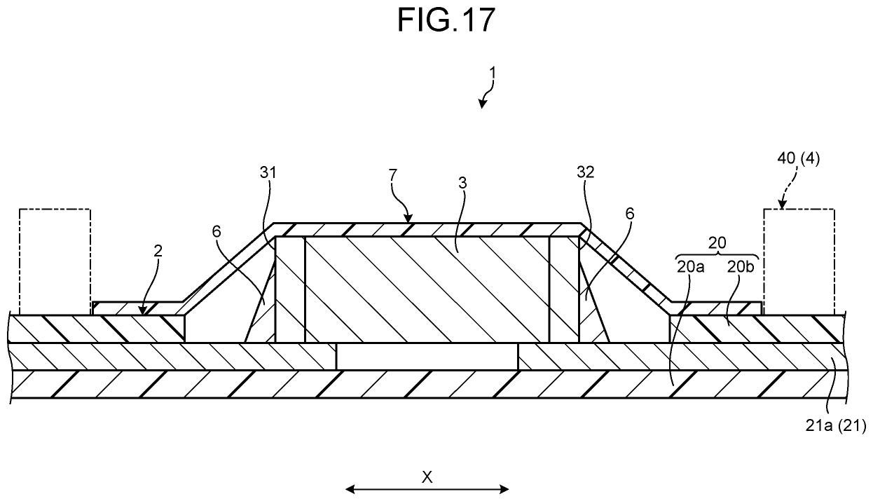

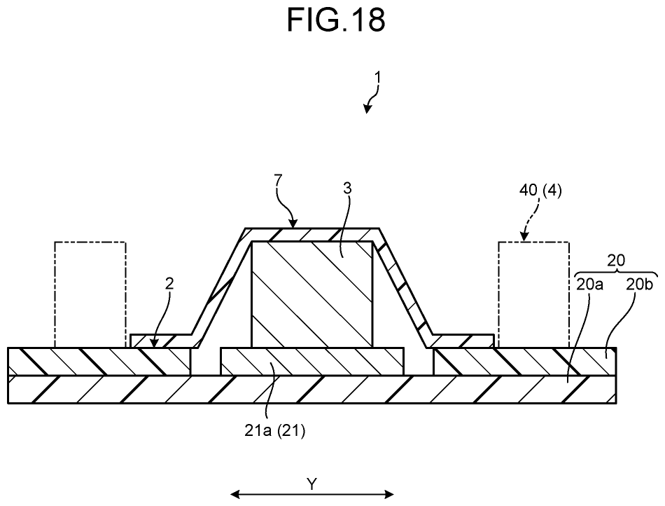

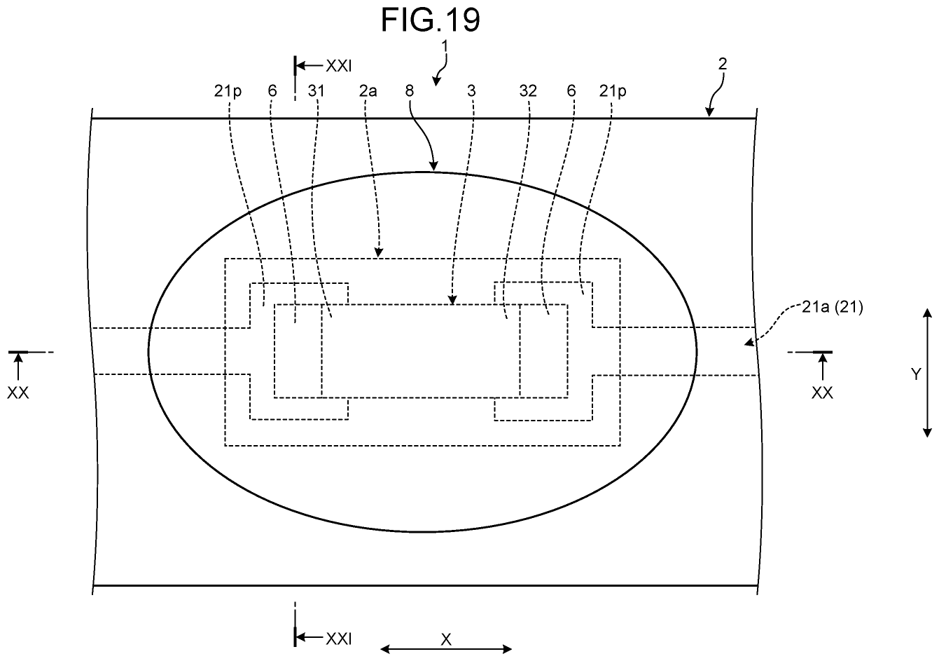

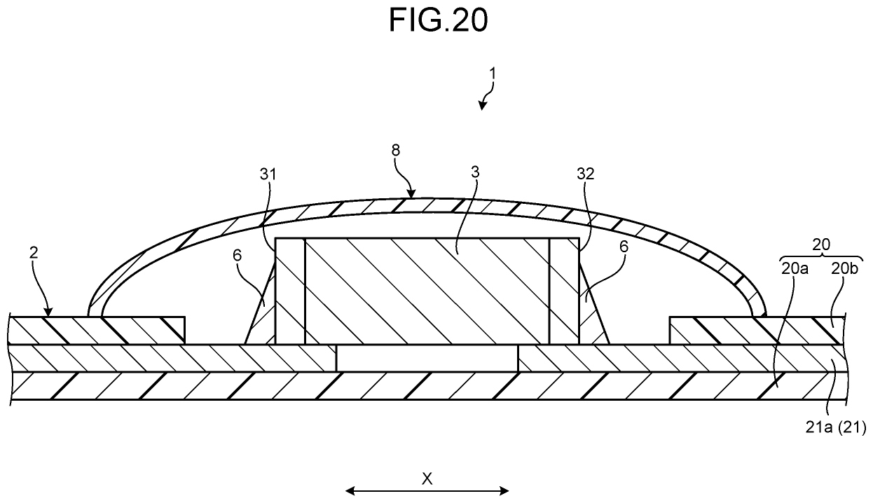

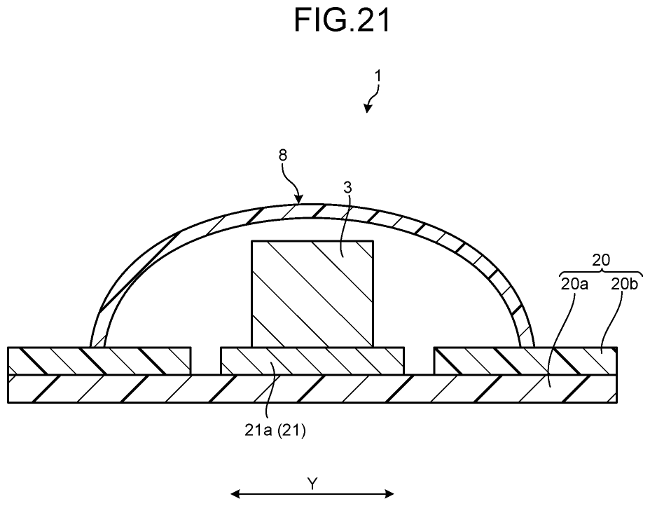

The following describes a second modification of the embodiment. FIG. 16 and FIG. 19 are plan views of the conductive module according to the second modification of the embodiment, and FIG. 17, FIG. 18, FIG. 20, and FIG. 21 are cross-sectional views of the conductive module according to the second modification of the embodiment. The second modification of the embodiment is different from the embodiment described above in that, for example, tape or a cup is used in place of the potting agent.

As illustrated in FIG. 16, the flexible printed wiring board 2 includes the circuit pattern 21a constituted of the first conductive layer 21. The rectangular exposed region 2a is disposed on the flexible printed wiring board 2. In the exposed region 2a, the pad 21p of the circuit pattern 21a is exposed. Tape 7 is attached to the coverlay 20b. The tape 7 adheres closely to the coverlay 20b, and covers the electronic component 3 and the exposed region 2a.

As illustrated in FIG. 17, the first terminal part 31 and the second terminal part 32 of the electronic component 3 are connected to the circuit pattern 21a by the solder 6. Both end parts in the first direction X of the tape 7 are bonded to the coverlay 20b. The tape 7 is waterproof tape having an insulation property.

As illustrated in FIG. 18, both end parts in the second direction Y of the tape 7 are bonded to the coverlay 20b. The tape 7 can seal the electronic component 3 in between the tape 7 and the flexible printed wiring board 2 to improve moisture resistance and insulation resistance of the electronic component 3. The tape 7 can easily ensure a thickness of an insulating layer covering the electronic component 3.

As illustrated in FIG. 17 and FIG. 18, the frame part 40 of the metal plate 4 may be fixed to the flexible printed wiring board 2. The frame part 40 is, for example, arranged to surround the tape 7. The frame part 40 may also be arranged to sandwich an edge of the tape 7 between the frame part 40 and the coverlay 20b.

As illustrated in FIG. 19 to FIG. 21, the electronic component 3 may be covered by a cup 8. The cup 8 is a waterproof cup formed of resin having an insulation property. As illustrated in FIG. 19, the cup 8 is fixed to the flexible printed wiring board 2 to surround the exposed region 2a. The cup 8 may be bonded to the coverlay 20b.

As illustrated in FIG. 20, both end parts in the first direction X of the cup 8 are fixed to the coverlay 20b. The cup 8 may cover the electronic component 3 in a state of being separated from the electronic component 3. As illustrated in FIG. 21, both end parts in the second direction Y of the cup 8 are fixed to the coverlay 20b. The cup 8 can easily ensure a thickness of an insulating layer covering the electronic component 3.

The frame part 40 of the metal plate 4 may be fixed to the flexible printed wiring board 2 illustrated in FIG. 19 to FIG. 21. The frame part 40 is, for example, arranged to surround the cup 8. The frame part 40 can suppress bending or stretching of the flexible printed wiring board 2, and can prevent the cup 8 from falling off the coverlay 20b.

The content disclosed in the embodiment and the modifications described above can be appropriately combined to be implemented.

The conductive module according to the present embodiment includes a metal plate including a frame part surrounding an electronic component and being fixed to a flexible printed wiring board, and a potting agent filled in a region surrounded by the frame part to cover the electronic component. In the conductive module according to the present embodiment, the frame part reinforces the flexible printed wiring board to protect the electronic component against external stress. The potting agent covers the electronic component to protect the electronic component. Thus, the conductive module according to the present embodiment exhibits an effect of appropriately protecting the electronic component mounted on the flexible printed wiring board.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A conductive module comprising:
a flexible printed wiring board;
an electronic component that is mounted on the flexible printed wiring board and connected to a circuit pattern of the flexible printed wiring board;
a metal plate that includes a frame part surrounding the electronic component and being fixed to the flexible printed wiring board; and
a potting agent that is filled in a region surrounded by the frame part to cover the electronic component.

2. The conductive module according to claim 1, wherein
the metal plate is a conductive busbar including a connection part fixed to a battery cell,
the connection part projects from the frame part toward a lateral side of the flexible printed wiring board, and
the frame part is connected to the circuit pattern.

3. The conductive module according to claim 1, wherein
the flexible printed wiring board includes a base film, a first conductive layer formed on a first surface of the base film, a first coverlay that covers the first conductive layer, a second conductive layer formed on a second surface of the base film, and a second coverlay that covers the second conductive layer,
the first surface is a surface opposed to the frame part, and the second surface is a surface on the opposite side of the first surface,
the circuit pattern includes a first wiring part, a second wiring part, and a third wiring part,
the first wiring part is constituted of the second conductive layer, and extends from a region on an outside of the frame part to an inside region surrounded by the frame part,
the second wiring part is constituted of the first conductive layer, arranged in the inside region, and connects the first wiring part to a first terminal part of the electronic component, and
the third wiring part is constituted of the first conductive layer, and connects a second terminal part of the electronic component to the frame part.

4. The conductive module according to claim 2, wherein
the flexible printed wiring board includes a base film, a first conductive layer formed on a first surface of the base film, a first coverlay that covers the first conductive layer, a second conductive layer formed on a second surface of the base film, and a second coverlay that covers the second conductive layer,
the first surface is a surface opposed to the frame part, and the second surface is a surface on the opposite side of the first surface,
the circuit pattern includes a first wiring part, a second wiring part, and a third wiring part,
the first wiring part is constituted of the second conductive layer, and extends from a region on an outside of the frame part to an inside region surrounded by the frame part,
the second wiring part is constituted of the first conductive layer, arranged in the inside region, and connects the first wiring part to a first terminal part of the electronic component, and
the third wiring part is constituted of the first conductive layer, and connects a second terminal part of the electronic component to the frame part.
